(19) United States
(12) Patent Application Publication
(10) Pub. No.: US 2026/0343939 A1
(43) Pub. Date: Oct. 29, 2026

(54) HIGH PERFORMANCE TRENCH MOSFET

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/296,584

(22) Filed: Aug. 11, 2025

Related U.S. Application Data
(60) Provisional application No. 63/796,093, filed on Apr. 28, 2025.
(60) Provisional application No. 63/800,202, filed on May 5, 2025.

(51) Int. Cl. H10D 30/66; H10D 30/01; H10D 62/10; H10D 64/27

(52) U.S. Cl. CPC H10D 30/668; H10D 30/0297; H10D 62/107; H10D 64/516; H10D 64/513

(57) ABSTRACT

A metal-oxide semiconductor field-effect transistor (MOSFET) includes a volume of semiconductor material, a gate, and a shielding region. The volume of semiconductor material includes a top, an opposite bottom spaced vertically from the top, a first side, and a laterally opposite second side spaced from the first side. The volume of semiconductor material forms a trench extending from the top and spaced between the sides. The trench includes opposite first and second trench sides. The gate is located within the trench. The shielding region is located below at least a portion of the gate and extends laterally beyond the second trench side toward the second side of the volume of semiconductor material.

### CROSS-REFERENCE TO RELATED APPLICATIONS

The current patent application claims the benefit under 35 U.S.C. § 119(e) of the priority date of U.S. Provisional Application Ser. No. 63/796,093; titled “HIGH PERFORMANCE TRENCH MOSFET”; and filed Apr. 28, 2025, and the priority date of U.S. Provisional Application Ser. No. 63/800,202; titled “INVERSE-T SHAPED TRENCH MOSFET”; and filed May 5, 2025. The Provisional Applications are hereby incorporated by reference, in their entirety, into the current patent application.

### TECHNICAL FIELD

The present disclosure relates to metal-oxide semiconductor field-effect transistors.

### BACKGROUND

A metal-oxide semiconductor field-effect transistor (MOSFET) is an active, voltage-controlled semiconductor device, in which varying an electrical voltage between a gate and a source controls an electrical current flowing through a semiconductor channel between a drain and the source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY OF THE INVENTION

In various examples of the present disclosure, a MOSFET includes a volume of semiconductor material, a gate, and a shielding region. The volume of semiconductor material includes a top, an opposite bottom spaced vertically from the top, a first side, and a laterally opposite second side spaced from the first side. The volume of semiconductor material forms a trench extending from the top and spaced between the sides. The trench includes opposite first and second trench sides. The gate is located within the trench. The shielding region is located below at least a portion of the gate and extends laterally beyond the second trench side toward the second side of the volume of semiconductor material.

In various examples of the present disclosure, a method of making a MOSFET includes: growing a volume of semiconductor material on a drain substrate; etching a trench in the volume of semiconductor material; placing a gate within the trench; and forming a shielding region located below at least a portion of the gate. The volume of semiconductor material includes a top, an opposite bottom spaced vertically from the top, a first side, and a laterally opposite second side spaced from the first side. The trench extends from the top and is spaced between the sides. The trench includes opposite first and second trench sides. The shielding region extends laterally beyond the second trench side trench toward the second side of the volume of semiconductor material.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a cross-sectional elevation view of an example trench MOSFET having a dopant shielding region;

FIG. 2 is a cross-sectional elevation view of an example trench MOSFET having a dielectric material shielding region;

FIG. 3 illustrates a method for manufacturing a trench MOSFET having a dopant shielding region in accordance with the examples of the present disclosure;

FIG. 4A is a cross-sectional elevation view of an example MOSFET following epitaxial growth of a volume of semiconductor material in accordance with the examples of the present disclosure;

FIG. 4B is a cross-sectional elevation view of an example MOSFET following a deposition of various dopants, including a dopant shielding region, into a volume of semiconductor material in accordance with the examples of the present disclosure;

FIG. 4C is a cross-sectional elevation view of an example MOSFET having a dopant shielding region following an etching operation in accordance with the examples of the present disclosure;

FIG. 4D is a cross-sectional elevation view of an example MOSFET having a dopant shielding region following deposition of a gate within a trench in accordance with the examples of the present disclosure;

FIG. 4E is a cross-sectional elevation view of an example MOSFET having a dopant shielding region following a contact placement operation in accordance with the examples of the present disclosure;

FIG. 5 illustrates a method for manufacturing a trench MOSFET having a dielectric material shielding region in accordance with the examples of the present disclosure;

FIG. 6A is a cross-sectional elevation view of an example MOSFET following epitaxial growth of a volume of semiconductor material and following deposition of various dopants into the volume of semiconductor material in accordance with the examples of the present disclosure;

FIG. 6B is a cross-sectional elevation view of an example MOSFET following a first etching operation in accordance with the examples of the present disclosure;

FIG. 6C is a cross-sectional elevation view of an example MOSFET following a second etching operation in accordance with the examples of the present disclosure;

FIG. 6D is a cross-sectional elevation view of an example MOSFET following formation of a dielectric material shielding region and gate deposition in accordance with the examples of the present disclosure; and

FIG. 6E is a cross-sectional elevation view of an example MOSFET having a dielectric material shielding region following a contact placement operation in accordance with the examples of the present disclosure.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a metal-oxide field effect transistor (MOSFET). The example MOSFET may be suitable for high-voltage applications, and may operate at a voltage greater than one thousand (1,000) Volts (V). More specifically, the example MOSFET may be rated for a voltage of around twelve hundred (1,200) V. It would be appreciated by one of ordinary skill in the art that the example MOSFET may be suitable for lower voltage applications without departing from the scope of the present disclosure.

The example MOSFET may include a volume of semiconductor material that has opposite first and second sides and defines a trench between the first and second sides. The trench may include opposite, laterally-spaced first and second trench sides. A gate may be placed in at least a portion of the trench. A shielding region may be located below the gate. The shielding region may include a dielectric material or a dopant, such as a P+ dopant. The shielding region may extend laterally toward the first side beyond the corresponding adjacent first trench side. Put differently, the shielding region may extend laterally so as to be closer to the first side than the first trench side is. In various examples, the shielding region may additionally or alternatively extend laterally toward the second side beyond the corresponding adjacent second trench side and/or so as to be closer to the second side than the second trench side is.

In various examples, the shielding region of the example MOSFET may provide improved gate insulation and may reduce an electric field below the gate, thereby improving device longevity and overall performance.

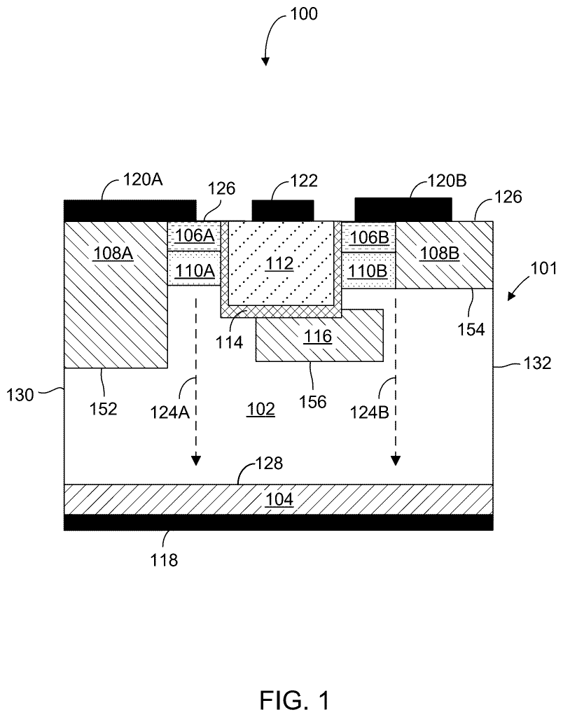

Referring to FIG. 1, an example of a MOSFET 100 is shown. The MOSFET 100 includes a volume of semiconductor material 101, a drain 104, a first source 106A, a second source 106B, a first P+ doped well region 108A, a second P+ doped well region 108B, a first P doped well region 110A, a second P doped well region 110B, a gate 112, a dielectric material 114, a shielding region 116, a drain contact 118, a first source contact 120A, a second source contact 120B, and a gate contact 122. The drain 104 may comprise an N+ doped drain substrate. The volume of semiconductor material 101 may be epitaxially grown or otherwise formed on the drain substrate 104. The volume of semiconductor material 101 may be initially formed as an N doped epitaxial semiconductor material, and may be modified by introduction of additional dopants (e.g., to form the sources 106A, 106B, wells 108A, 108B, and P doped well regions 110A, 110B).

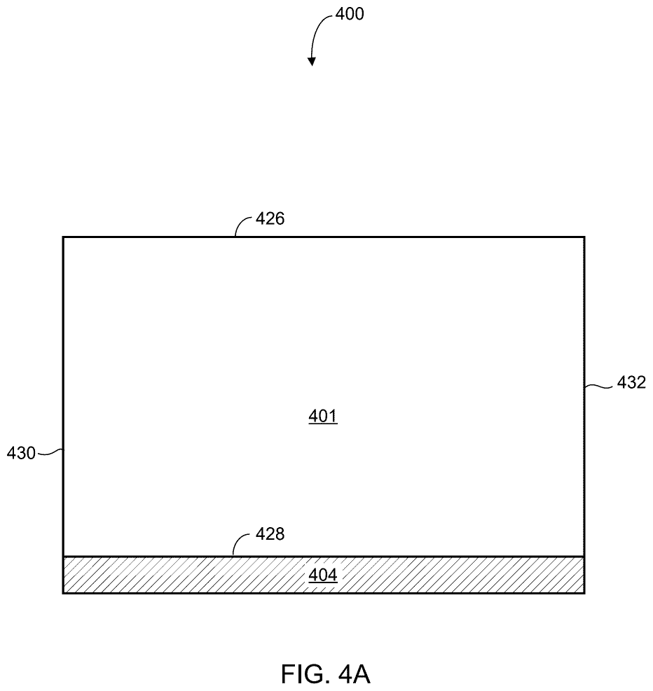

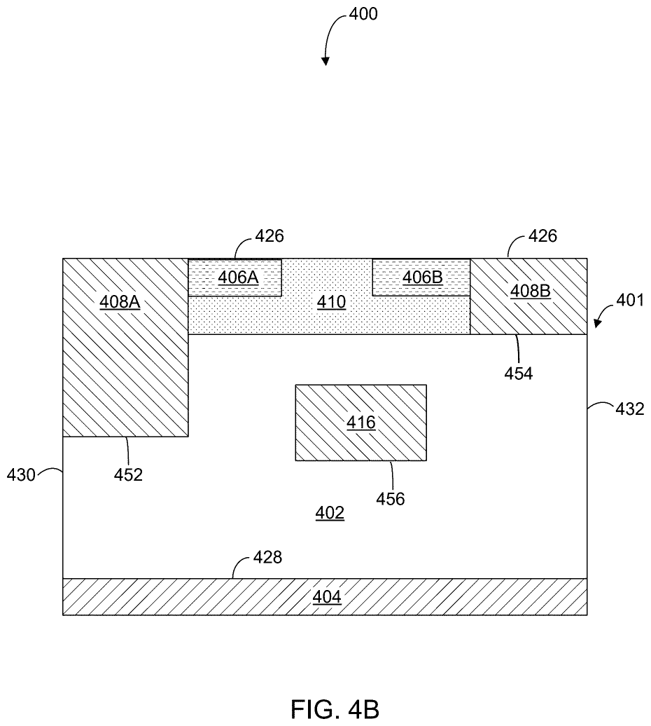

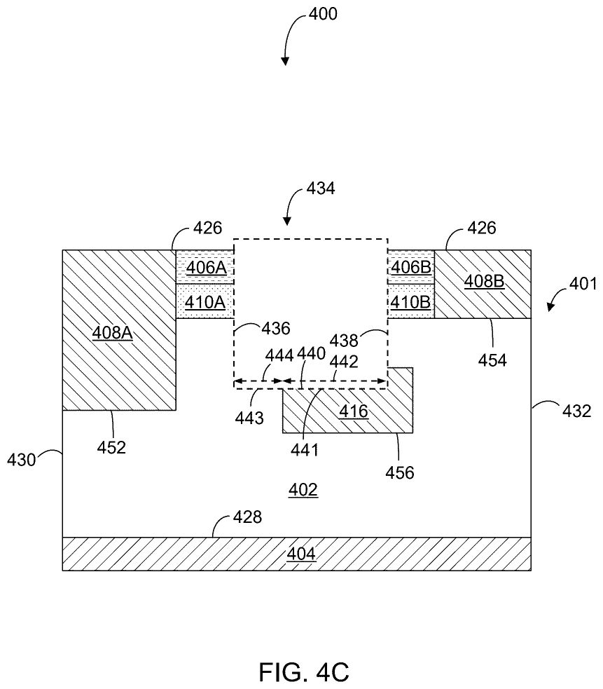

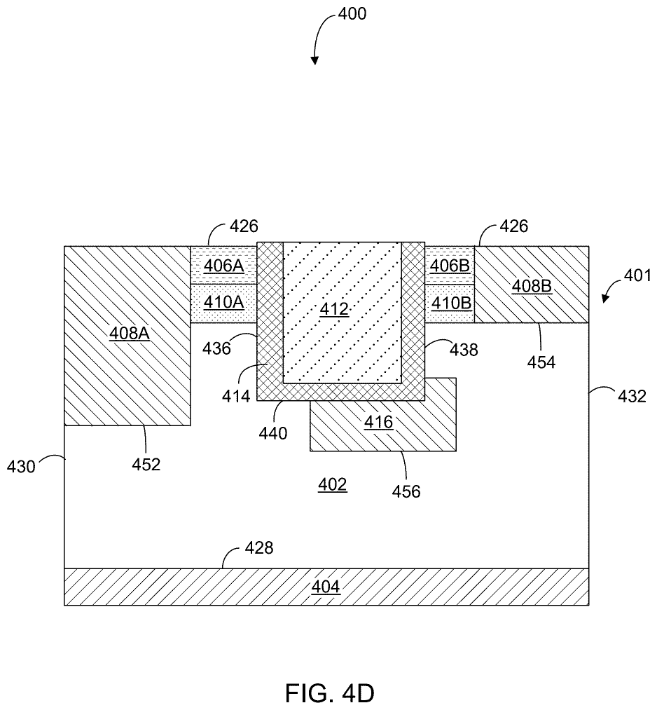

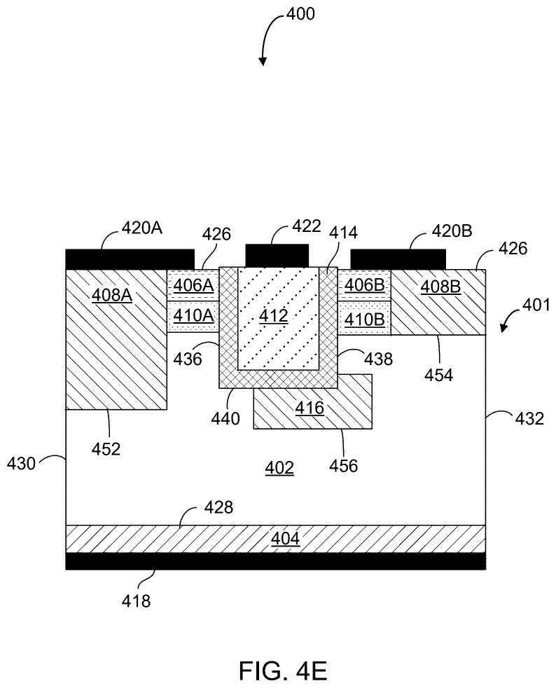

The volume of semiconductor material 101 includes a top 126, an opposite bottom 128 vertically spaced from the top 126, a first side 130, and a laterally opposite second side 132 spaced from the first side 130. The volume of semiconductor material 101 defines a trench (e.g., a trench 434 as shown in FIG. 4C) extending from the top 126 toward the bottom 128 between first and second sides 130, 132. The volume of semiconductor material 101 additionally includes a drift region 102. The volume of semiconductor material 101 and drift region 102 may include an N doped epitaxial material. The drain 104 is located adjacent the bottom 128.

Each of the first and second sources 106A, 106B may include an N+ dopant deposited (e.g., via ion implantation) into or otherwise formed within the volume of semiconductor material 101 adjacent the top 126. The first source contact 120A is placed on the top 126 adjacent the first source 106A. The second source contact 120B is placed on the top 126 adjacent the second source 106B.

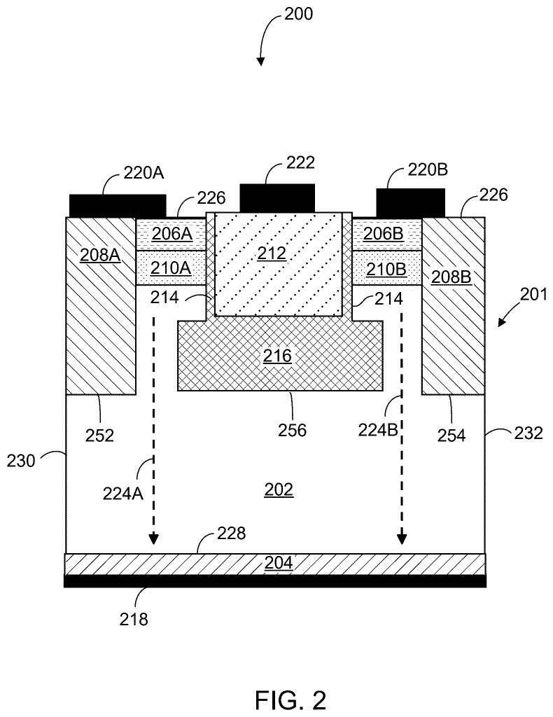

The first and second P+ doped well regions 108A, 108B may include a P+ dopant deposited (e.g., via ion implantation) into or otherwise formed into the volume of semiconductor material adjacent the top 126 and respectively adjacent the first and second sides 130, 132. The first P+ doped well region 108A may form a first lowermost junction 152 with the drift region 102. The second P+ doped well region 108B may form a second lowermost junction 154 with the drift region 102. The shielding region 116 may form a third lowermost junction 156 with the drift region 102. The first lowermost junction 152 may be closer to the bottom 128 than either of the second and third lowermost junctions 154, 156 are. The third lowermost junction 156 may be closer to the bottom 128 than the second lowermost junction 154 is. In an alternative example, the first and second lowermost junctions 154, 156 may be equally spaced from the bottom 128 (e.g., as shown in FIG. 2) without departing from the scope of the present disclosure. The first and third lowermost junctions 152, 156 may be equally spaced from the bottom 128 without departing from the scope of the present disclosure.

Each of the first and second P doped well regions 110A, 110B may include a P dopant deposited (e.g., via ion implantation) into or otherwise formed below the respective sources 106A, 106B. The first P doped well region 110A may extend between the trench and the first P+ doped well region 108A. The second P doped well region 110B may extend between the trench and the second P+ doped well region 108B.

The gate 112 is located within the trench. The dielectric material 114 is located between the gate 112 and all sides of the trench (e.g., between first and second trench sides 436, 438 and a trench bottom 440 as shown in FIG. 4C). The gate 112 may include or comprise a doped polysilicon material. The dielectric material 114 may include or comprise an oxide, such as silicon oxide (SiO2).

The shielding region 116 may be located below at least a portion of the gate 112 and below the trench. The shielding region 116 may extend laterally beyond the second trench side toward the second side 132 (e.g., shielding region 416 extends toward second side 432 beyond second trench side 438 as shown in FIG. 4C). At least a portion of the shielding region 116 may underlie the second source 106B and P doped well region 110B. The shielding region 116 may be vertically offset from both the second source 106B and the P doped well region 110B such that at least a portion of the drift region 102 (e.g., N doped epitaxial material) may extend between the shielding region 116 and the P doped well region 110B and the second source 106B.

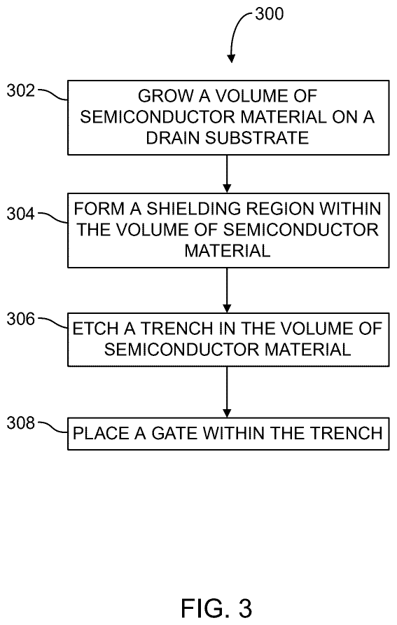

The shielding region 116 may be located adjacent at least a portion of the trench bottom (e.g., shielding region 116 is adjacent a trench bottom portion 441 as shown in FIG. 4C), which is discussed in more detail below in connection with the method 300 of FIG. 3. In various examples, a junction between a shielding region and a trench bottom portion is formed.

In various examples, the shielding region 116 may include a P+ dopant that is deposited (e.g., via ion implantation) into or otherwise formed within the volume of semiconductor material 101.

During operation, a voltage applied to the gate contact 122 may form channels 124A, 124B though which charge carriers may move in a flow of electrical energy between the first and second sources 106A, 106B on the one hand and the drain 104 on the other hand. It will be understood by one of ordinary skill in the art that the dashed line representing the channels 124A, 124B are merely representative and charge carriers moving through the channels 124A, 124B do not necessarily follow a straight line.

The shielding region 116 may shield the gate 112 and the source 106B from being exposed to a high electrical field (e.g., formed near or resulting from the drain 104), thereby improving device longevity and reducing switching losses.

It will be appreciated that the example MOSFET 100 is an N-channel MOSFET. However, certain aspects of the example MOSFET might be applicable to P-channel MOSFETs.

Referring to FIG. 2, an example of a MOSFET 200 is shown. The MOSFET 200 includes a volume of semiconductor material 201, a drain 204, a first source 206A, a second source 206B, a first P+ doped well region 208A, a second P+ doped well region 208B, a first P doped well region 210A, a second P doped well region 210B, a gate 212, a dielectric material 214, a shielding region 216, a drain contact 218, a first source contact 220A, a second source contact 220B, and a gate contact 222. The drain 204 may comprise an N+ doped drain substrate. The volume of semiconductor material 201 may be epitaxially grown or otherwise formed on the drain substrate 204. The volume of semiconductor material 201 may be initially formed as an N doped epitaxial semiconductor material, and may be modified by introduction of additional dopants (e.g., to form the sources 206A, 206B, wells 208A, 208B, and P doped well regions 210A, 210B).

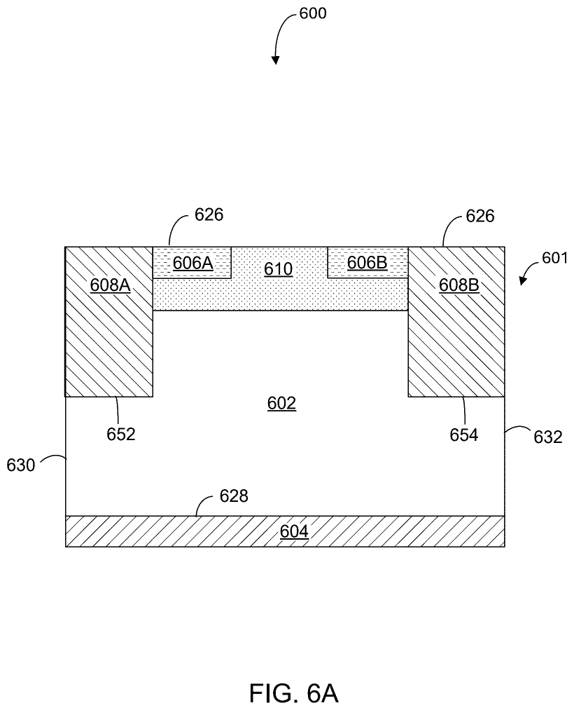

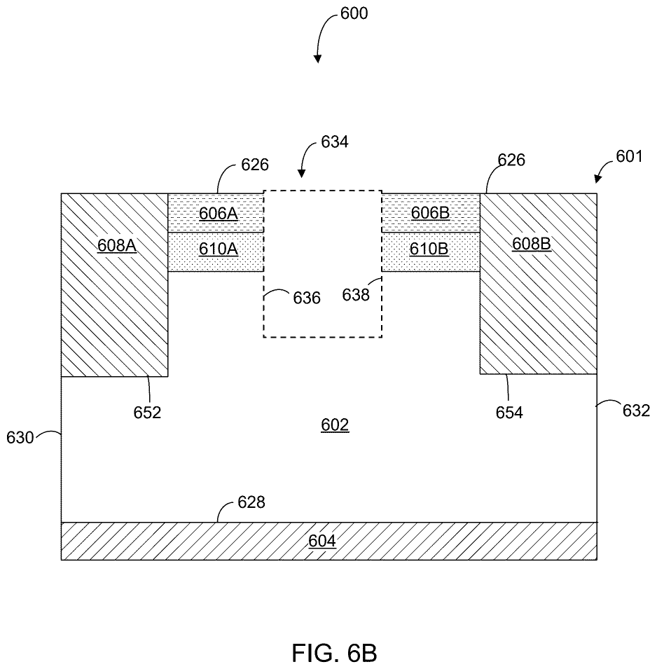

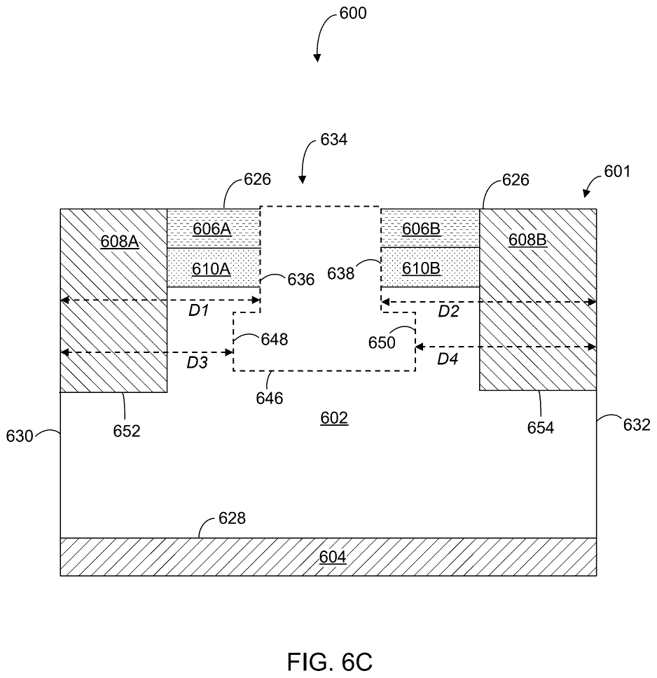

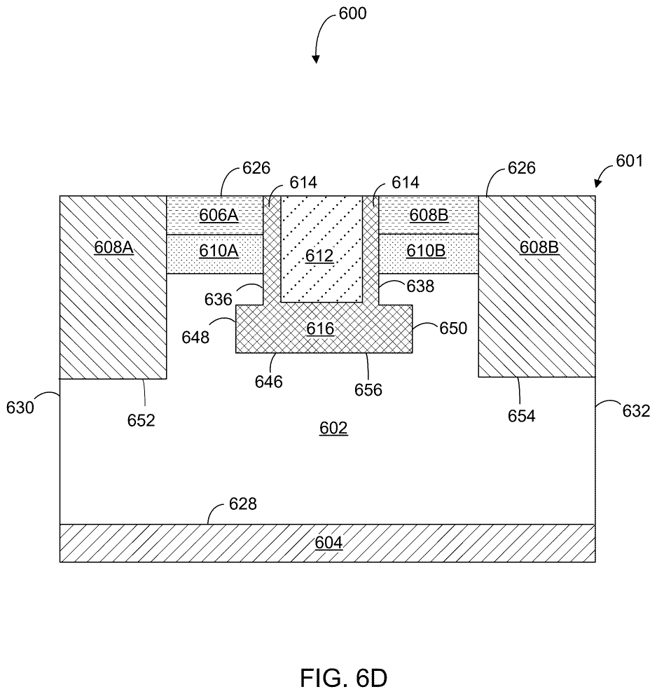

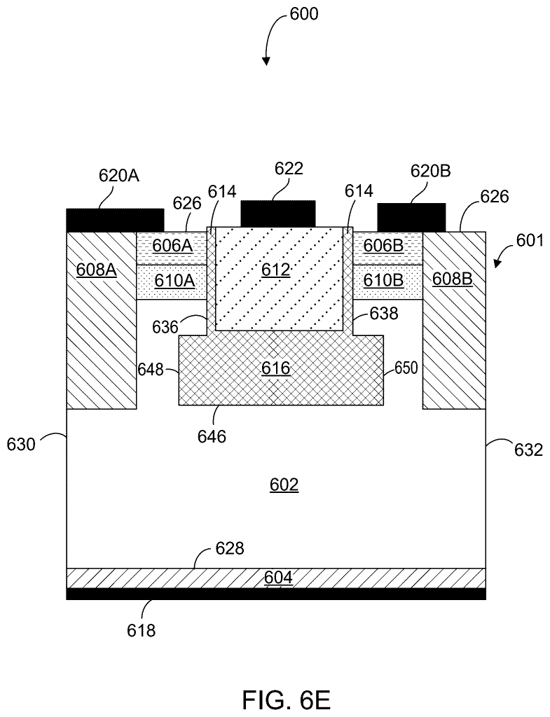

The volume of semiconductor material 201 includes a top 226, an opposite bottom 228 vertically spaced from the top 226, a first side 230, and a laterally opposite second side 232 spaced from the first side 230. The volume of semiconductor material 201 defines a trench (e.g., a trench 634 as shown in FIG. 6B) extending from the top 226 toward the bottom 228 between first and second sides 230, 232. The volume of semiconductor material 201 additionally includes a drift region 202. The volume of semiconductor material 201 and the drift region 202 may include an N doped epitaxial material. The drain 204 is located adjacent the bottom 228.

Each of the first and second sources 206A, 206B may include an N+ dopant deposited (e.g., via ion implantation) into or otherwise formed within the volume of semiconductor material 201 adjacent the top 226. The first source contact 220A is placed on the top 226 adjacent the first source 206A. The second source contact 220B is placed on the top 226 adjacent the second source 206B.

The first and second P+ doped well regions 208A, 208B may include a P+ dopant deposited (e.g., via ion implantation) into or otherwise formed into the volume of semiconductor material adjacent the top 226 and respectively adjacent the first and second sides 230, 232. The first P+ doped well region 208A may form a first lowermost junction 252 with the drift region 202. The second P+ doped well region 208B may form a second lowermost junction 254 with the drift region 202. The shielding region 216 may form a third lowermost junction 256 with the drift region 202. In various examples, the first and second lowermost junctions 252, 254 may be closer to the bottom 228 than the third lowermost junction 256 is. The first and second lowermost junctions 252, 254 may be equally spaced from the bottom 228. Accordingly, the first and second P+ doped well regions 208A, 208B may be symmetrical.

In an alternative example, the first, second, and third lowermost junctions 252, 254, 256 may be equally spaced from the bottom 228, or the third lowermost junction 256 may be closer to the bottom 228 than either of the first or second junctions 252, 254 without departing from the scope of the present disclosure. Similarly, the first lowermost junction 252 may be closer to the bottom 228 than the second lowermost junction 254 is, and the third lowermost junction 256 may be closer to the bottom 228 than the second lowermost junction 254 (e.g., as shown in FIG. 1.) is without departing from the scope of the present disclosure.

Each of the first and second P doped well regions 210A, 210B may include a P dopant deposited (e.g., via ion implantation) into or otherwise formed below the respective sources 206A, 206B. The first P doped well region 210A may extend between the trench and the first P+ doped well region 208A. The second P doped well region 210B may extend between the trench and the second P+ doped well region 208B.

The gate 212 is located within the trench. The dielectric material 214 is located between the gate 212 and upper sides of the trench (e.g., between the gate 612 and the first and second trench sides 636, 638 as shown in FIG. 6B). The gate 212 may include or comprise a doped polysilicon material. The dielectric material 214 may include or comprise an oxide (e.g., SiO2).

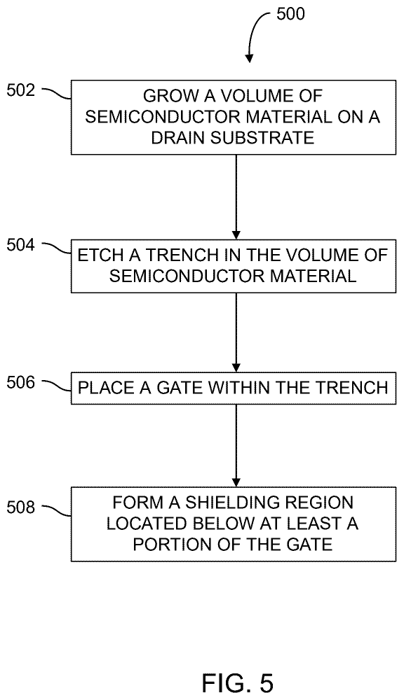

The shielding region 216 may be located below the gate 212 and within a portion of the trench (e.g., shielding region 616 extends between third and fourth trench sides 648, 650 and extends between the gate 612 and a trench bottom 646 as shown in FIG. 6C). The shielding region 216 may extend laterally beyond each of the first and second trench sides (e.g., region 616 extends laterally outward beyond first and second trench sides 636, 638 as shown in FIG. 6C) respectively toward the first side 230 and second side 232. Portions of the shielding region 216 may underlie respective ones of the first and second sources 206A, 206B and of the P doped well regions 210A, 210B. The shielding region 216 may be vertically offset from each of the first and second sources 206A, 206B and each of the first and second P doped well regions 210A, 210B such that at least a portion of the drift region 202 (e.g., N doped epitaxial material) may extend between the shielding region 216 and the first and second P doped well regions 210A, 210B. Additional details regarding the shielding region 216 are discussed below in connection with the method 500 of FIG. 5.

In various examples, the shielding region 216 may include a dielectric material that is formed within the trench. The shielding region 216 may comprise the same dielectric material (e.g., SiO2) as the dielectric material 214. The shielding region 216 may shield the gate 212, the first source 206A, and the second source 206B from exposure to a high electrical field (e.g., formed near or resulting from the drain 204), thereby improving device longevity and reducing switching losses.

During operation, a voltage applied to the gate contact 222 may form channels 224A, 224B through which charge carriers may move in a flow of electrical energy between the first and second sources 206A, 206B on the one hand and the drain 204 on the other hand. It will be understood by one of ordinary skill in the art that the dashed line representing the channels 224A, 224B are merely representative and charge carriers moving through the channels 224A, 224B do not necessarily follow a straight line.

The shielding region 216 may shield the gate 212, the first source 206A, and the second source 206B from being exposed to a high electrical field (e.g., formed near or resulting from the drain 204), thereby improving device longevity and reducing switching losses.

It will be appreciated that the example MOSFET 200 is an N-channel MOSFET. However, certain aspects of the example MOSFET might be applicable to P-channel MOSFETs.

Referring to FIG. 3, an example of a method 300 of manufacturing a MOSFET having a dopant shielding region, such as the MOSFET 100 described above, may include the operations set forth below. Referring additionally to FIGS. 4A-4E, example results of various operations on a MOSFET 400 are shown.

At operation 302, a volume of semiconductor material 401 is epitaxially grown or otherwise formed on a drain substrate 404, as seen in FIG. 4A. The volume of semiconductor material 401 includes a top 426, an opposite bottom 428 vertically spaced from the top 426, a first side 430 and a laterally opposite second side 432 laterally spaced from the first side 430. The drain substrate 404 may include an N+ doped substrate material. The volume of semiconductor material 401 may be initially formed as an N doped epitaxial semiconductor material, and may be modified by introduction of additional dopants (e.g., to form the sources 406A, 406B, wells 408A, 408B, and P doped well regions 410A, 410B).

At operation 304, a shielding region 416 is formed within the volume of semiconductor material 401. The shielding region 416 may be deposited (e.g., via ion implantation) into the volume of semiconductor material 416. The shielding region 416 may include a P+ dopant.

The shielding region 416 may be deposited as part of a dopant deposition operation, in which any combination of one or more of first and second sources 406A, 406B, first and second wells 408A, 408B, and a P doped well region 410 are deposited (e.g., via ion implantation) into the volume of semiconductor material 401. The first and second wells 408A, 408B may be laterally spaced apart. The first and second sources 406A, 406B may be laterally spaced apart.

The first well 408A may be deposited adjacent the first side 430. The second well 408B may be deposited adjacent the second side 432. The P doped well region 410 may be deposited adjacent the top 426 and between the first and second wells 408A, 408B. The first source 406A may be deposited adjacent the first well 408A. The second source 406B may be deposited adjacent the second well 408B.

The first well 408A forms a first lowermost junction 452 with a drift region 402 of the volume of semiconductor material 401. The well 408B forms a second lowermost junction 454 with the drift region 402. The shielding region 416 forms a third lowermost junction 456 with the drift region 402. As discussed in connection with FIG. 1, the first lowermost junction 452 may be closer to the bottom 428 than either of the second or third lowermost junctions 454, 456 is. The third lowermost junction 456 may be closer to the bottom 428 than the second lowermost junction 454 is. In an alternative example, the first and third lowermost junctions 452, 456 may be equally spaced from the bottom 428.

In various examples, one or more masks may be utilized to deposit the doped regions within the volume of semiconductor material 401. For example, a first mask may be placed across the top 426 to implant the shielding region 416, a second mask may be placed across the top 426 to implant the well 408A, and so on. If the first and second wells 408A, 408B are asymmetrical (e.g., as shown in FIG. 4B and discussed in connection with FIG. 1), two (2) masks may be used to implant the first and second wells 408A, 408B. If the first and second wells 408A, 408B are symmetrical (e.g., as discussed in connection with FIG. 2), one (1) mask may be used to implant both of the wells 408A, 408B.

At operation 306, a trench 434 is etched into the volume of semiconductor material 401. The trench 434 includes a first trench side 436, a laterally opposite second trench side 438, and a trench bottom 440 extending between the first and second trench sides 436, 438.

Etching of the trench 434 may split the P doped well region 410 to form first and second P doped well regions 410A, 410B. The first source 406A may be located between the first well 408A and the first trench side 436. The first P doped well region 410A may underlie the first source 406A and may be located between the first well 408A and the first trench side 436. The second source 406B may be located between the second well 408B and the second trench side 438. The second P doped well region 410B may underlie second source 406B and may be located between the second well 408B and the second trench side 438. The first and second wells 408A, 408B and the first and second P doped well regions 410A, 410B may contact a drift region 402 of the volume of semiconductor material 401. The drift region 402 may include an N doped epitaxial semiconductor material.

The trench bottom 440 includes a first trench bottom portion 443 and a second trench bottom portion 441. The first portion 441 forms a first junction with the shielding region 416 spanning a first distance 442. The second portion 443 forms a second junction with the drift region 402 spanning a second distance 444. The first and second distances 442, 444 may be equal. Accordingly, the first and second portions 441, 443 may have a same lateral dimension (e.g., as defined by the distances 442, 444). Accordingly, the shielding region 416 may span about half of the trench bottom 440. However, in various examples, such as the illustrated example, the first distance 442 may be about twice the second distance 444. Other relationships between such first and second distances are within the scope of the present disclosure.

At operation 308, a gate 412 is placed within the trench 434. The gate 412 may be placed adjacent a dielectric material 414. The gate 412 may include a doped polysilicon material. The dielectric material 414 may include an oxide (e.g., SiO2). The dielectric material 414 may line each of the trench sides 436, 438 and the trench bottom 440, such that the gate 412 is insulated from the surrounding components (e.g., the sources 406A, 406B, the drift region 402, and the P doped well regions 410A, 410B). The dielectric material 414 may be formed (e.g., grown) following etching of the trench 434. In various examples, dielectric material may initially be deposited or otherwise formed in and may substantially fill the trench 434, and a subsequent additional etching operation may remove portions of the dielectric material to form the liner of dielectric material 414 and generate a cavity into which the gate 412 may be placed.

Various contacts are also placed on the MOSFET 400. The contacts include a drain contact 418, first and second source contacts 420A, 420B, and a gate contact 422. The drain contact 418 may be located adjacent the drain 404. The first source contact 420A may be located adjacent the first P+ doped well region 408A and the first source 406A. The second source contact 420B may be located adjacent the second P+ doped well region 408B and the second source 406B.

The shielding region 416 may be located below the gate 412, the second source 406B, and the second P doped well region 410B. The shielding region 416 may be vertically offset from each of the source 406B and the second P doped well region 410B, such that a portion of the drift region 402 is present between the shielding region 416 and the P doped well region 410B and between the shielding region 416 and the second source 406B. One of ordinary skill will appreciate that the positioning of well and shielding regions of FIG. 4E may be laterally mirrored-such that, e.g., a larger well is on the “right” and a smaller well is on the “left,” with a shielding region extending toward the “left” side-within the scope of the present disclosure.

Referring to FIG. 5, an example method 500 of manufacturing a MOSFET having a dielectric shielding region, such as the MOSFET 200 described above, may include the operations set forth below. Referring additionally to FIGS. 6A-6E, example results of various operations on a MOSFET 200 are shown.

At operation 502, a volume of semiconductor material 601 is epitaxially grown or otherwise formed on a drain substrate 604 as shown in FIG. 6A. The volume of semiconductor material 601 includes a top 626, an opposite bottom 628 vertically spaced from the top 626, a first side 630 and a laterally opposite second side 632 laterally spaced from the first side 630. The drain substrate 604 may include an N+ doped substrate material. The volume of semiconductor material 601 may be initially formed as an N doped epitaxial semiconductor material, and may be modified by introduction of additional dopants (e.g., to form the sources 606A, 606B, wells 608A, 608B, and P doped well regions 610A, 610B).

Various dopants may be deposited (e.g., via ion implantation) into the volume of semiconductor material 601. A first well 608A may be deposited adjacent the first side 630. A second well 608B may be deposited adjacent the second side 632. The first and second wells 608A, 608B may include P+ doped well regions. A P doped well region 610 may be deposited adjacent the top 626 and between the first and second wells 608A, 608B. A first source 606A may be deposited adjacent the first well 608A. A second source 606B may be deposited adjacent the second well 608B. The first and second wells 608A, 608B may be laterally spaced apart. The first and second sources 606A, 606B may be laterally spaced apart.

At operation 504, a trench 634 is etched into the volume of semiconductor material 601, as shown in FIGS. 6B and 6C. A first portion of the trench 634 may be etched as shown in FIG. 6B. A second portion of the trench 634 may be etched as shown in FIG. 6C. The second portion of the trench 634 may include a third trench side 648, a laterally spaced opposite fourth trench side 650, and a trench bottom 646. The first portion may be etched, in whole or in part, before the second portion is etched. In various examples, the first and second portions of the trench 634 may be etched in the same operation, without departing from the spirit of the present disclosure.

Etching of the trench 634 may split the P doped well region 610 to form first and second P doped well regions 610A, 610B. The first source 606A may be located between the first well 608A and the first trench side 636. The first P doped well region 610A may underlie the first source 606A and may be located between the first well 608A and the first trench side 636. The second source 606B may be located between the second well 608B and the second trench side 638. The second P doped well region 610B may underlie second source 606B and may be located between the second well 608B and the second trench side 638. The first and second wells 608A, 608B and the first and second P doped well regions 610A, 610B may contact a drift region 602 of the volume of semiconductor material 601. The drift region 602 may include an N doped epitaxial semiconductor material, except for where other dopants (e.g., N+ doped sources 606A, 606B, P+ doped wells 608A, 608B, and P doped well regions 610A, 610B) are present.

The first trench side 636 and the first side 630 may be separated laterally or along a lateral axis by a first distance D1. The second trench side 638 and the second side 632 may be separated laterally or along a lateral axis by a second distance D2. The third trench side 648 and the first side 630 may be separated laterally or along a lateral axis by a third distance D3. The fourth trench side 650 and the second side 632 may be separated laterally or along a lateral axis by a fourth distance D4. The first distance D1 and the second distance D2 may be equal. The third distance D3 and the fourth distance D4 may be equal. The first distance D1 may be greater than both the third distance D3 and the fourth distance D4. The second distance D2 may be greater than both the third distance D3 and the fourth distance D4.

At operation 506, a gate 612 is placed within the trench 634, as shown in FIG. 6D. The gate 612 may be placed adjacent a dielectric material 614. The gate 612 may include a doped polysilicon material. The dielectric material 614 may include an oxide (e.g., SiO2). The dielectric material 614 may line each of the trench sides 636, 638, such that the gate 612 is insulated from the surrounding components (e.g., the sources 606A, 606B, the drift region 602, and the P doped well regions 610A, 610B). The dielectric material 614 may be formed (e.g., grown) following etching of the trench 634.

At operation 508, a shielding region 616 is formed below at least a portion of the gate 612. The shielding region 616 may extend between the third and fourth trench sides 648, 650 and across the trench bottom 646. The shielding region 616 may include a dielectric material. More specifically, the shielding region 616 may include an oxide (e.g., SiO2). The shielding region 616 may be formed from the same material as the dielectric material 614.

In various examples, the shielding region 616 may be formed prior to placement of the gate 614. For example, the shielding region 616 may be formed (e.g., grown) at the same time as the dielectric material 614. In various examples, dielectric material may initially be deposited or otherwise formed in and may substantially fill the trench 634 and shielding region 616, and a subsequent additional etching operation may remove portions of the dielectric material, without disturbing the dielectric material of the shielding region 616, to form the liner of dielectric material 614 and generate a cavity into which the gate 612 may be placed.

The shielding region 616 may be vertically offset from the first and second sources 606A, 606B and the first and second P doped well regions 610A, 610B such that portions of the drift region 602 are present between the shielding region 616 and the first P doped well region 610A, between the shielding region 616 and the first source 606A, between the shielding region 616 and the second P doped well region 610B, and between the shielding region 616 and the second source 606B.

The first well 608A forms a first lowermost junction 652 with the drift region 602. The second well 608B forms a second lowermost junction 654 with the drift region 602. The shielding region 616 forms a third lowermost junction 656 with the drift region 602. As discussed in connection with FIG. 2, the first lowermost junction 652 and the second lowermost junction 654 may be equally spaced from the bottom 628, such that the first and second wells 608A, 608B are symmetrical. The third lowermost junction 656 may be spaced farther from the bottom 628 than both of the first and second lowermost junctions 652, 654 are. In an alternative example, the first, second and third lowermost junctions 652, 654, 656 may be equally spaced from the bottom 628.

### Feature Combinations

In accordance with various examples of the present disclosure, a MOSFET may include a volume of semiconductor material, a gate, and a shielding region. The volume of semiconductor material may include a top, an opposite bottom spaced vertically from the top, a first side, and a laterally opposite second side spaced from the first side. The volume of semiconductor material forms a trench extending from the top and spaced between the sides. The trench may include opposite first and second trench sides. The gate may be located within the trench. The shielding region may be located below at least a portion of the gate and may extend laterally beyond the second trench side toward the second side of the volume of semiconductor material.

In various examples of the present disclosure, a method of making MOSFET may include: growing a volume of semiconductor material on a drain substrate; etching a trench in the volume of semiconductor material; placing a gate within the trench; and forming a shielding region located below at least a portion of the gate. The volume of semiconductor material may include a top, an opposite bottom spaced vertically from the top, a first side, and a laterally opposite second side spaced from the first side. The trench may extend from the top and may be spaced between the sides. The trench may include opposite first and second trench sides. The shielding region may extend laterally beyond the second trench side trench toward the second side of the volume of semiconductor material.

In combination with any of the previous examples, a source of a volume of semiconductor material may be located adjacent a trench. At least a portion of a shielding region may underly and may be vertically offset below the source.

In combination with any of the previous examples, a trench may include opposite third and fourth trench sides and a trench bottom may extend between the third and fourth trench sides. A first trench side may be laterally spaced from a first side of a volume of semiconductor material by a first distance. A second trench side may be laterally spaced from a second side of the volume of semiconductor material by a second distance. The third trench side may be laterally spaced from the first side of the volume of semiconductor material by a third distance. The fourth trench side may be laterally spaced from the second side of the volume of semiconductor material by a fourth distance. The first and second distances may be greater than both the third and fourth distances. A shielding region may extend between the third and fourth trench sides.

In combination with any of the previous examples, a shielding region may include a dielectric material.

In combination with any of the previous examples, a trench may include a trench bottom extending between first and second trench sides. A MOSFET may include a drift region of a volume of semiconductor material. The trench bottom may include a first portion forming a first junction with a shielding region and a second portion forming a second junction with the drift region.

In combination with any of the previous examples, first and second portions of a trench may have an equal size.

In combination with any of the previous examples, a shielding region may include a P+ dopant.

In combination with any of the previous examples, a MOSFET may include laterally spaced apart first and second wells located within a volume of semiconductor material, laterally spaced apart first and second sources located within the volume of semiconductor material, a drift region of the volume of semiconductor material extending between a first side and a second side, and a drain located adjacent a bottom. The first well may be located adjacent the first side of the volume of semiconductor material. The second well may be located adjacent the second side of the volume of semiconductor material. The first source may be located between the first well and a first trench side. The second source may be located between the second well and a second trench side. The drain may extend between the first and second sides of the volume of semiconductor material.

In combination with any of the previous examples, first and second wells may be symmetrical.

In combination with any of the previous examples, a trench may include a trench bottom extending between at least first and second trench sides. A first well, a second well, and a trench bottom may each have lowermost junctions with the drift region. The lowermost junction of the first well may be closer to the bottom than the lowermost junction of the trench bottom is. The lowermost junction of the trench bottom may be closer to the bottom than the lowermost junction of the second well is.

In combination with any of the previous examples, first and second wells may include a P+ dopant. First and second sources may include an N+ dopant. A volume of semiconductor material may include a N-type epitaxial dopant. A drift region may include an N dopant.

In combination with any of the previous examples, a first channel may extend between a first source and a drain. A second channel may extend between a second source and the drain.

In combination with any of the previous examples, a MOSFET may include a gate contact located adjacent a gate, a first source contact located adjacent a first well and a first source, a second source contact located adjacent a second well and a second source, and a drain contact located adjacent a drain.

In combination with any of the previous examples, a method of making MOSFET may include: depositing laterally spaced apart first and second wells within a volume of semiconductor material, the first well being located adjacent a first side of the volume of semiconductor material, the second well being located adjacent a second side of the volume of semiconductor material; and depositing laterally spaced apart first and second sources within the volume of semiconductor material, the first source being located between the first well and a first trench side, the second source being located between the second well and a second trench side. A shielding region may underly and be vertically offset from the second source.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., MOSFET), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations (measured in parts per cubic centimeter) for contact implants may be approximately between 10\hat{ }18 and 10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A metal-oxide semiconductor field-effect transistor (MOSFET) comprising:
a volume of semiconductor material including a top, an opposite bottom spaced vertically from the top, a first side, and a laterally opposite second side spaced from the first side, the volume of semiconductor material forming a trench extending from the top and spaced between the sides, the trench including opposite first and second trench sides;
a gate located within the trench; and
a shielding region located below at least a portion of the gate and extending laterally beyond the second trench side toward the second side of the volume of semiconductor material.

2. The MOSFET of claim 1, comprising:
a source of the volume of semiconductor material located adjacent the trench,
wherein at least a portion of the shielding region underlies and is vertically offset below the source.

3. The MOSFET of claim 1,
the trench including opposite third and fourth trench sides and a trench bottom extending between the third and fourth trench sides,
the first trench side being laterally spaced from the first side of the volume of semiconductor material by a first distance,
the second trench side being laterally spaced from the second side of the volume of semiconductor material by a second distance,
the third trench side being laterally spaced from the first side of the volume of semiconductor material by a third distance,
the fourth trench side being laterally spaced from the second side of the volume of semiconductor material by a fourth distance,
the first and second distances being greater than both the third and fourth distances, the shielding region extending between the third and fourth trench sides.

4. The MOSFET of claim 1,
the shielding region including a dielectric material.

5. The MOSFET of claim 1, wherein the trench includes a trench bottom extending between the first and second trench sides, comprising:
a drift region of the volume of semiconductor material,
the trench bottom including a first portion forming a first junction with the shielding region and a second portion forming a second junction with the drift region.

6. The MOSFET of claim 5,
the first and second portions of the trench bottom having an equal size.

7. The MOSFET of claim 1,
the shielding region including a P+ dopant.

8. The MOSFET of claim 1, comprising:
laterally spaced apart first and second wells located within the volume of semiconductor material, the first well being located adjacent the first side of the volume of semiconductor material, the second well being located adjacent the second side of the volume of semiconductor material;
laterally spaced apart first and second sources located within the volume of semiconductor material, the first source being located between the first well and the first trench side, the second source being located between the second well and the second trench side;
a drift region of the volume of semiconductor material extending between the first side and the second side; and
a drain located adjacent the bottom, the drain extending between the first and second sides of the volume of semiconductor material.

9. The MOSFET of claim 8,
the first and second wells being symmetrical.

10. The MOSFET of claim 8,
the trench including a trench bottom extending between at least the first and second trench sides,
the first well, the second well and the trench bottom each having lowermost junctions with the drift region,
the lowermost junction of the first well being closer to the bottom than the lowermost junction of the trench bottom is,
the lowermost junction of the trench bottom being closer to the bottom than the lowermost junction of the second well is.

11. The MOSFET of claim 8,
the first and second wells including a P+ dopant,
the first and second sources including an N+ dopant,
the volume of semiconductor material including a N-type epitaxial dopant,
the drift region including an N dopant.

12. The MOSFET of claim 8, comprising:
a first channel extending between the first source and the drain; and
a second channel extending between the second source and the drain.

13. The MOSFET of claim 8, comprising:
a gate contact located adjacent the gate;
a first source contact located adjacent the first well and the first source;
a second source contact located adjacent the second well and the second source; and
a drain contact located adjacent the drain.

14. A method of making a metal-oxide semiconductor field-effect transistor (MOSFET), comprising:
growing a volume of semiconductor material on a drain substrate, the volume of semiconductor material including a top, an opposite bottom spaced vertically from the top, a first side, and a laterally opposite second side spaced from the first side;
etching a trench in the volume of semiconductor material, the trench extending from the top and being spaced between the sides, the trench including opposite first and second trench sides;
placing a gate within the trench; and
forming a shielding region located below at least a portion of the gate, the shielding region extending laterally beyond the second trench side trench toward the second side of the volume of semiconductor material.

15. The method of claim 14,
the trench including opposite third and fourth trench sides and a trench bottom extending between the third and fourth trench sides,
the first trench side being laterally spaced from the first side of the volume of semiconductor material by a first distance,
the second trench side being laterally spaced from the second side of the volume of semiconductor material by a second distance,
the third trench side being laterally spaced from the first side of the volume of semiconductor material by a third distance,
the fourth trench side being laterally spaced from the second side of the volume of semiconductor material by a fourth distance,
the first and second distances being greater than both the third and fourth distances,
the shielding region extending between the third and fourth trench sides,
the shielding region including a dielectric material.

16. The method of claim 14, the trench including a trench bottom extending between the first and second trench sides, wherein forming the shielding region includes:
depositing the shielding region within the volume of semiconductor material,
the trench bottom including a first portion forming a junction with the shielding region and a second portion forming a junction with a drift region of the volume of semiconductor material,
the shielding region including a P+ dopant.

17. The method of claim 14, comprising:
depositing laterally spaced apart first and second wells within the volume of semiconductor material, the first well being located adjacent the first side of the volume of semiconductor material, the second well being located adjacent the second side of the volume of semiconductor material; and
depositing laterally spaced apart first and second sources within the volume of semiconductor material, the first source being located between the first well and the first trench side, the second source being located between the second well and the second trench side, wherein the shielding region underlies and is vertically offset from the second source.

18. The method of claim 17, comprising:
placing a gate contact adjacent the gate;
placing a first source contact adjacent the first well and the first source;
placing a second source contact adjacent the second well and the second source; and
placing a drain contact adjacent the drain substrate.

19. The method of claim 17,
the first and second wells being symmetrical.

20. The method of claim 17,
the trench including a trench bottom extending between at least the first and second trench sides,
the first well, the second well, and the trench bottom each having lowermost junctions with the drift region,
the lowermost junction of the first well being closer to the bottom than the lowermost junction of the trench bottom is,
the lowermost junction of the trench bottom being closer to the bottom than the lowermost junction of the second well is.
